(19) United States
(12) Patent Application Publication
(10) Pub. No.: US 2020/0300949 A1
(43) Pub. Date: Sep. 24, 2020

(54) CHEMICAL EXCHANGE SATURATION TRANSFER - MAGNETIC RESONANCE IMAGING (CEST-MRI) SEQUENCE GENERATING METHOD, APPARATUS AND READABLE STORAGE MEDIUM

(71) Applicants: Siemens Healthineers Ltd., Shanghai (CN); Zhejiang University, Hangzhou (CN)

(72) Inventors: Yi Zhang, Hangzhou (CN); Dan Wu, Hangzhou (CN); Yi Sun, Shanghai (CN)

(73) Assignees: Siemens Healthineers Ltd., Shanghai (CN); Zhejiang University, Hangzhou (CN)

(21) Appl. No.: 16/823,608

(22) Filed: Mar. 19, 2020

(30) Foreign Application Priority Data
Mar. 19, 2019 (CN) 201910210000.7

(51) Int. Cl. G01R 33/48; G01R 33/54

(52) U.S. Cl. CPC G01R 33/4828; G01R 33/543

(57) ABSTRACT

The present disclosure related to techniques for implementing Chemical Exchange Saturation Transfer-Magnetic Resonance Imaging (CEST-MRI) sequence generation. The techniques include starting a CEST-MRI scanning process, and generating and transmitting a CEST pre-saturation pulse. When transmission of the CEST pre-saturation pulse has ended, the MRI device generates and transmits a fat-suppression pulse. When transmission of the fat-suppression pulse has ended, the MRI device generates and transmits an excitation pulse. When transmission of the excitation pulse has ended, the MRI device generates and transmits multiple non-slice-selective refocusing square-wave pulses. The present disclosure functions to increase the spatial coverage and MR signal acquisition speed of CEST-MRI imaging.

### CROSS-REFERENCE TO RELATED APPLICATIONS

The present application claims the benefit of the filing date of China patent application no. 201910210000.7, filed on Mar. 19, 2019, the contents of which are incorporated herein by reference in their entirety.

### TECHNICAL FIELD

The disclosure relates to the technical field of MRI (Magnetic Resonance Imaging) and, in particular, to a Chemical Exchange Saturation Transfer (CEST)-MRI sequence generating method, apparatus, and readable storage medium.

### BACKGROUND

In MRI, a radio frequency (RF) pulse of a specific frequency is applied to a human body in a static magnetic field such that hydrogen protons in the human body are excited and experience the phenomenon of magnetic resonance. When the pulse is stopped, the protons give rise to MR (magnetic resonance) signals in the course of relaxation. An MR image is created by processing such as MR signal reception, spatial encoding and image reconstruction.

As MRI technology has developed, CEST has become a focus of attention in the field of MRI. CEST is used for the imaging of solute molecules which are free in water and have a concentration that is smaller than that of water molecules by several orders of magnitude. Due to the fact that the hydrogen nuclei in these solute molecules are in a different chemical environment, the resonant frequency will experience a slight shift compared with hydrogen nuclei of water molecules, even though they are in the same external magnetic field; this shift is referred to as chemical shift. In CEST research, solute molecules form a set, referred to as a solute pool; free water molecules are referred to as a water pool. When a pre-saturation RF pulse is applied on the resonant frequency of the solute pool, the hydrogen protons of the solute pool are saturated, and chemical exchange subsequently occurs in the two pools, causing the saturated hydrogen protons in the solute pool to be transferred to the water pool, replacing non-saturated hydrogen protons in the water pool; after a period of accumulation, when imaging is performed, signals collected in the water pool will experience additional attenuation, and many important physiological parameters can be estimated from the attenuated signals.

In CEST imaging experiments, the pre-saturation RF pulse is not only applied on the resonant frequency of the solute pool; a large number of frequency points are chosen on a frequency axis of a certain range for the application of pulses, and after saturation, MRI signals of the water pool are separately acquired at each frequency point. Due to the existence of the CEST mechanism, these MRI signals have obvious attenuation compared with a signal in the case where no pre-saturation pulse is applied, and CEST contrast agent information is analyzed quantitatively according to this attenuation so as to obtain some important physiological chemical parameters or structural information of an imaging region.

In order to apply CEST imaging in conventional clinical settings, the spatial coverage and MR signal acquisition speed thereof must meet certain conditions, and furthermore, a final CEST image must be substantially artifact-free.

### SUMMARY

To solve the abovementioned problem, the present disclosure provides embodiments including a CEST-MRI sequence generating method, CEST-MRI sequence generating apparatus, and readable storage medium to increase the spatial coverage and MR signal acquisition speed of CEST-MRI imaging.

To achieve the abovementioned objective, the present application provides the following technical solution:

In an embodiment, a Chemical Exchange Saturation Transfer-Magnetic Resonance Imaging (CEST-MRI) sequence generating method is disclosed, comprising:

a CEST-MRI scanning process starting, and an MRI device generating a CEST pre-saturation pulse and transmitting the same;

when transmission of the CEST pre-saturation pulse has ended, the MRI device generates a fat-suppression pulse and transmits the same;

when transmission of the fat-suppression pulse has ended, the MRI device generates an excitation pulse and transmits the same;

when transmission of the excitation pulse has ended, the MRI device generates multiple non-slice-selective refocusing square-wave pulses and transmits the same.

Through the embodiment described above, the spatial coverage and MR signal acquisition speed of CEST-MRI imaging are increased by using non-slice-selective refocusing square-wave pulses.

The CEST pre-saturation pulse and the fat-suppression pulse may both be non-slice-selective pulses.

The excitation pulse may be e.g. a square-wave pulse or a non-square-wave pulse.

As an example range, 50≤number of refocusing square-wave pulses≤250;

As an example width, 0.8 ms≤width of refocusing square-wave pulses≤1.5 ms;

As an example interval, 2 ms≤interval between adjacent refocusing square-wave pulses≤5 ms.

Through the embodiment described above, the MR signal acquisition speed is increased by using refocusing square-wave pulses with a short width and a short interval.

In an embodiment, each of the refocusing square-wave pulses may have the same flip angle;

Alternatively, in other embodiments, for T1 and T2 values of imaged tissue and a k-space signal intensity distribution curve to be realized, the Bloch equations may be used to work out the flip angles of each of the refocusing square-wave pulses.

Through the embodiment described above, when refocusing square-wave pulses with different flip angles are used, the time present on a transverse axis is extended when MR signals are acquired, the number of refocusing operations is increased, and the MR signal acquisition speed is thereby increased.

In an embodiment, the steps of the MRI device generating an excitation pulse and transmitting the same, and generating multiple non-slice-selective refocusing square-wave pulses and transmitting the same when transmission of the excitation pulse has ended, is disclosed, and comprise:

the MRI device generating a SPACE (Sampling Perfection with Application-optimized Contrasts by using different flip angle Evolutions) sequence and transmitting the same.

Through the embodiment described above, by using the SPACE sequence, it is not only possible to increase the spatial coverage and MR signal acquisition speed of CEST-MRI imaging, but also possible to significantly reduce susceptibility artifacts.

In an embodiment, a Chemical Exchange Saturation Transfer-Magnetic Resonance Imaging (CEST-MRI) sequence generating apparatus, associated with an MRI device is disclosed, which comprises:

a pre-saturation pulse generating and transmitting module/circuitry, which generates a pre-saturation pulse and transmits the same when a CEST-MRI scanning process starts;

a fat-suppression pulse generating and transmitting module/circuitry, which generates a fat-suppression pulse and transmits the same when transmission of the pre-saturation pulse has ended;

an excitation and refocusing pulse generating and transmitting module/circuitry, which generates an excitation pulse and transmits the same when transmission of the fat-suppression pulse has ended, and generates multiple non-slice-selective refocusing square-wave pulses and transmits the same when transmission of the excitation pulse has ended.

The pre-saturation pulse generated and transmitted by the pre-saturation pulse generating and transmitting module/circuitry may be a non-slice-selective pulse;

the fat-suppression pulse generated and transmitted by the fat-suppression pulse generating and transmitting module/circuitry may be a non-slice-selective pulse.

The excitation pulse generated by the excitation and refocusing pulse generating and transmitting module/circuitry may be e.g. a square-wave pulse or a non-square-wave pulse.

The refocusing square-wave pulses generated by the excitation and refocusing pulse generating and transmitting module/circuitry may e.g. satisfy one or more of the following conditions: 50≤number of refocusing square-wave pulses≤250, 0.8 ms≤width of refocusing square-wave pulses≤1.5 ms, 2 ms≤interval between refocusing square-wave pulses≤5 ms.

In some embodiments, each of the refocusing square-wave pulses generated by the excitation and refocusing pulse generating and transmitting module/circuitry have the same flip angle;

Alternatively, in other embodiments, for T1 and T2 values of imaged tissue and a k-space signal intensity distribution curve to be realized, the Bloch equations may be used to work out the flip angles of each of the refocusing square-wave pulses.

The excitation and refocusing pulse generating and transmitting module/circuitry may be used for generating a SPACE sequence and transmitting the same.

Embodiments also include a non-transitory computer-readable storage medium having instructions stored thereon (e.g. a computer program stored thereon) that, when executed by one or more processors, may cause the one or more processors (or various components associated with the one or more processors such as, e.g. an MRI device as discussed herein) to realize one or more steps of the Chemical Exchange Saturation Transfer-Magnetic Resonance Imaging (CEST-MRI) sequence-generating method as described in any one of the embodiments herein.

In an embodiment, a Chemical Exchange Saturation Transfer-Magnetic Resonance Imaging (CEST-MRI) sequence generating apparatus is disclosed, comprising: one or more processors and a memory;

an application program executable by the processor may be stored in the memory, and used to cause the one or more processors to perform a step of the Chemical Exchange Saturation Transfer-Magnetic Resonance Imaging (CEST-MRI) sequence generating method as described in any one of the embodiments herein.

In the present disclosure, by constructing CEST-MRI as a CEST pre-saturation pulse, a fat-suppression pulse, an excitation pulse, and multiple non-slice-selective refocusing square-wave pulses, the spatial coverage and MR signal acquisition speed of CEST-MRI imaging are increased.

### BRIEF DESCRIPTION OF THE DRAWINGS/FIGURES

Further details and advantages regarding the current disclosure may be taken from the following description of example embodiments taken in conjunction with the drawings, in which:

FIG. 1 is a flow chart of an example CEST-MRI sequence generating method in accordance with one or more embodiments of the present disclosure.

FIG. 2 is a flow chart of an example CEST-MRI sequence generating method in accordance with one or more embodiments of the present disclosure.

FIG. 3 is an example demonstrative diagram of a scan performed on brain tissue using a CEST-MRI sequence in accordance with one or more embodiments of the present disclosure.

FIG. 4 is an example source S0 image in the sagittal direction of the entire brain obtained in a scan of brain tissue using the CEST-MRI sequence in accordance with one or more embodiments of the present disclosure.

FIG. 5 is an APTw image calculated according to the source S0 image shown in FIG. 4, with the skull stripped away, in accordance with one or more embodiments of the present disclosure.

FIG. 6 is an APTw image in the transverse direction obtained in a scan of brain tissue using the CEST-MRI sequence proposed in accordance with one or more embodiments of the present disclosure.

FIG. 7 is an APTw image in the coronal direction obtained in a scan of brain tissue using the CEST-MRI sequence proposed in accordance with one or more embodiments of the present disclosure.

FIG. 8 is a CEST-MRI sequence generating apparatus provided in accordance with one or more embodiments of the present disclosure.

FIG. 9 is a CEST-MRI sequence generating apparatus provided in accordance with one or more embodiments of the present disclosure.

### KEY TO THE DRAWINGS

| Label | Meaning |
|---|---|
| 101-104 | steps |
| 201-203 | steps |
| 80 | CEST-MRI sequence generating apparatus provided in an |
| | embodiment of the present disclosure |
| 81 | pre-saturation pulse generating and transmitting module/ |
| | circuitry |
| 82 | fat-suppression pulse generating and transmitting module/ |
| | circuitry |
| 83 | excitation and refocusing pulse generating and transmitting |
| | module/circuitry |
| 90 | CEST-MRI sequence generating apparatus provided in another |
| | embodiment of the present disclosure |
| 91 | processor(s) |
| 92 | memory(ies) |

### DETAILED DESCRIPTION

To clarify the objective, technical solution, and advantages of the present disclosure, the technical solution of the present disclosure is explained in detail below on the basis of embodiments with reference to the accompanying drawings.

For example, “a” and “the” in the singular form used in the description of the present disclosure and the attached claims are also intended to include the plural form, unless clearly specified otherwise herein.

The present disclosure is explained in detail below:

FIG. 1 is a flow chart of an example CEST-MRI sequence generating method in accordance with one or more embodiments of the present disclosure. In particular, FIG. 1 is a flow chart of an example CEST-MRI sequence generating method provided in an embodiment of the present disclosure, having the following specific steps:

Step 101: a CEST-MRI scanning process starts, and an MRI device generates a CEST pre-saturation pulse and transmits the same.

Step 102: when transmission of the CEST pre-saturation pulse has ended, the MRI device generates a fat-suppression pulse and transmits the same. In embodiments, the CEST pre-saturation pulse and fat-suppression pulse may both be non-slice-selective pulses.

Step 103: when transmission of the fat-suppression pulse has ended, the MRI device generates an excitation pulse and transmits the same.

Step 104: when transmission of the excitation pulse has ended, the MRI device generates multiple non-slice-selective refocusing square-wave pulses and transmits the same. In embodiments, the excitation pulse may be a square-wave pulse or a non-square-wave pulse. When the excitation pulse is a square-wave pulse, the range of values of the width of the square-wave pulse may be, for example: 0.4 ms≤width of square-wave pulse≤1 ms. Moreover, in embodiments, the ranges of values of the number and width of the refocusing square-wave pulses and the interval between adjacent pulses may be, for example: 50≤number of refocusing square-wave pulses≤250, 0.8 ms≤width of refocusing square-wave pulses≤1.5 ms, 2 ms≤interval between adjacent refocusing square-wave pulses≤5 ms.

In embodiments, a flip angle of a refocusing square-wave pulse sequence may vary, i.e. the flip angles of all refocusing square-wave pulses may be the same, generally being set to an angle in the range of 60° to 180°. Alternatively, other embodiments include the flip angles of each of the refocusing square-wave pulses being partially different (e.g. some refocusing square wave pulses may have a different flip angle) or completely different (e.g. each of the refocusing square wave pulses may have a different flip angle). For instance, for T1 and T2 values of imaged tissue and a k-space signal intensity distribution curve to be realized, the Bloch equations may be used to calculate the flip angles of each of the refocusing square-wave pulses. The distribution of k-space signal intensity thus determines the contrast of the image that is finally generated.

In embodiments, in steps 103 and 104, the MRI device may generate a SPACE (Sampling Perfection with Application-optimized Contrasts by using different flip angle Evolutions) sequence and transmit the same.

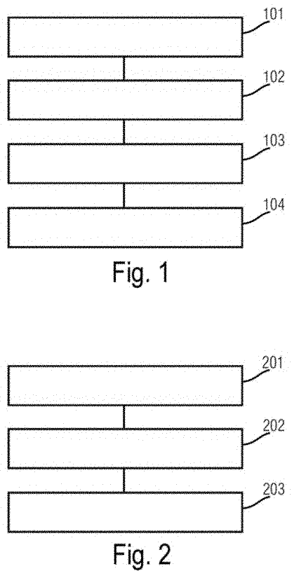

FIG. 2 is a flow chart of an example CEST-MRI sequence generating method in accordance with one or more embodiments of the present disclosure. In particular, FIG. 2 is a flow chart of a CEST-MRI sequence generating method provided in another embodiment of the present disclosure, having the following specific steps:

Step 201: a CEST-MRI scanning process starts, and an MRI device generates a preset number of non-slice-selective CEST pre-saturation pulse(s), and transmits the same.

The type and number of the CEST pre-saturation pulses, the width of each pulse, and the interval between adjacent pulses may be set according to the particular tissue being scanned.

Examples of suitable pulse types include, for instance, Gaussian pulses, square-wave pulses, etc.

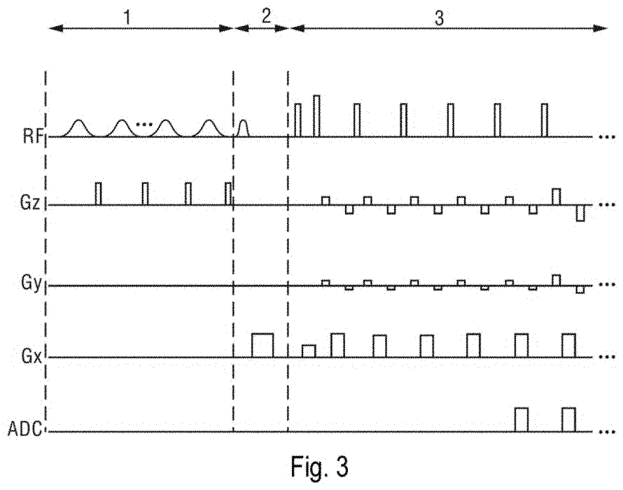

FIG. 3 is an example demonstrative diagram of a scan performed on brain tissue using a CEST-MRI sequence in accordance with one or more embodiments of the present disclosure. In particular, FIG. 3 is a demonstrative diagram of a scan performed on brain tissue using a CEST-MRI sequence proposed in an embodiment of the present disclosure. As shown in FIG. 3, RF denotes the CEST-MRI sequence; Gx, Gy and Gz denote gradient fields of the CEST-MRI sequence in the x, y and z directions, respectively, ADC denotes a data readout sequence of the CEST-MRI sequence, and sequence 1 denotes CEST pre-saturation pulses. Continuing this example, the CEST pre-saturation pulses may be 10 frequency-selective Gaussian pulses with a width of 100 ms (milliseconds) and an interval of 10 ms, wherein a gradient pulse with a width of 5 ms and a strength of 15 mT/m (milliteslas/meter) may be applied in the z direction, i.e. the slice direction within an interval of 10 ms.

Step 202: when transmission of the CEST pre-saturation pulse(s) has ended, the MRI device generates a non-slice-selective fat-suppression pulse of a preset type and transmits the same.

The type of the fat-suppression pulse may be set according to the particular fat tissue being scanned.

For example, when brain tissue is being scanned, as shown in FIG. 3, a Spectral Pre-saturation with Inversion Recovery (SPIR) pulse may be used. When transmission of the SPIR pulse has ended, a gradient pulse may be applied in the x direction.

Step 203: when transmission of the fat-suppression pulse has ended, the MRI device generates a SPACE sequence and transmits the same.

The SPACE sequence consists of an excitation pulse and multiple non-slice-selective refocusing pulses. The refocusing pulses are square-wave pulses, and have variable flip angles.

For example, when brain tissue is being scanned, sequence 3 in the RF sequence shown in FIG. 3 is a SPACE sequence. The refocusing pulses may first be four preparatory pulses, with flip angles of 149°, 122°, 119° and 120°, respectively, followed by echo pulses with a constant flip angle of 120°, wherein gradient pulses are applied in the z, x and y directions, respectively, during intervals between adjacent refocusing pulses.

Application examples of the present disclosure are given below:

A magnetic resonance system having a magnetic field strength of 3 T and a 64-channel head-and-neck coil performs a CEST-MRI scan of the brains of 5 healthy volunteers.

A scan sequence, like the RF sequence shown in FIG. 3, includes three parts: 1. a CEST pre-saturation sequence; 2. a SPIR fat-suppression pulse; and 3. a SPACE sequence. wherein:

1) The CEST pre-saturation sequence comprises ten frequency-selective Gaussian pulses of length 100 ms, with each pulse having a root mean square (RMS) power of 2.5 uT;

adjacent Gaussian pulses are separated by an interval of 10 ms, within which interval a gradient field of width 5 ms and a strength of 15 mT/m is applied.

2) The SPACE sequence has an excitation pulse and multiple refocusing square-wave pulses; before entering the constant 120° refocusing pulses, there are four preparatory refocusing pulses, with the following flip angles, respectively, of 149°, 122°, 119° and 120°.

The following MR signal acquisition parameters are used: field of view (FOV)=212×212×201 mm3, matrix size=76×76×72, resolution=2.79×2.79×2.79 mm3, repetition time (TR)=3 s (seconds), echo time (TE)=17 ms (milliseconds), turbo factor=140, Generalized Autocalibrating Partially Parallel Acquisition (GRAPPA) factor=2×2, the imaging direction is the sagittal direction, and imaging is Amide Proton Transfer-weighted (APTw) imaging having non-saturation (S0) and saturation frequencies; APT imaging is a branch technique of CEST imaging, the frequency offsets used being ±3 ppm, ±3.5 ppm and ±4 ppm, and the scan duration being 5 minutes.

Further continuing this application example, a gradient echo sequence is used to scan the brain and to obtain a B0 field frequency offset diagram, with TR=30 ms, and two echo times TE=4.92 ms and 9.84 ms. Finally, an APTw image is calculated using a CEST image resulting from correction of the B0 field frequency offset diagram.

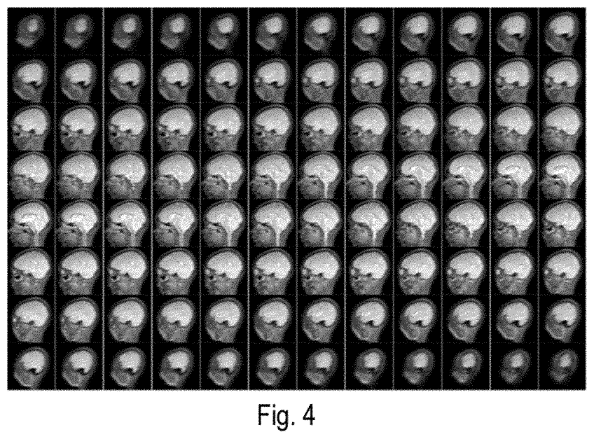

FIG. 4 is an example source S0 image in the sagittal direction of the entire brain obtained in a scan of brain tissue using the CEST-MRI sequence in accordance with one or more embodiments of the present disclosure. In the example shown in FIG. 4, the image is an image in the sagittal direction of the entire brain.

It can be seen from the image that no obvious susceptibility artifacts have been found in the entire image, even close to the nose cavity. This reflects the robustness of the CEST-MRI sequence proposed in an embodiment of the present disclosure.

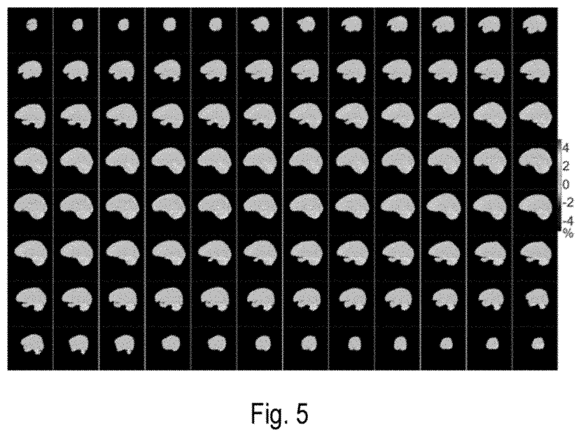

FIG. 5 is an APTw image calculated according to the source S0 image shown in FIG. 4, with the skull stripped away, in accordance with one or more embodiments of the present disclosure. It can be seen in FIG. 5 that when the CEST-MRI sequence proposed in an embodiment of the present disclosure is used, the APTw image finally obtained is a high-quality whole-brain image having good uniformity, wherein a cerebellum region has slight artifacts. This might be caused by less-than-ideal shimming of this region, and may be improved through region self-adaptive shimming.

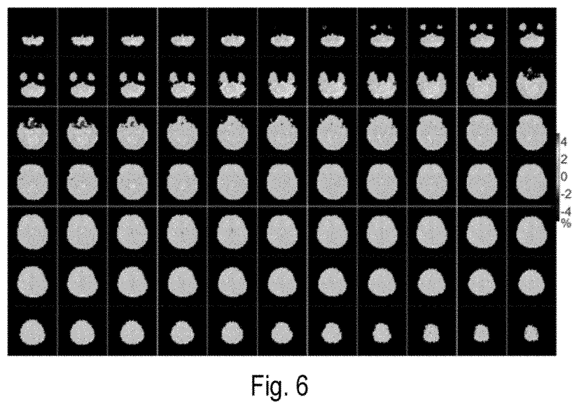

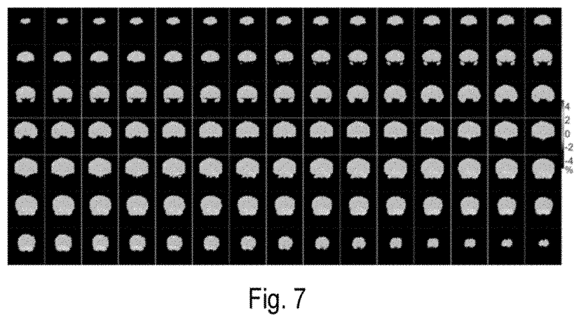

FIGS. 6 and 7 are APTw images in the transverse and coronal directions respectively. Similarly, these APTw images are of high quality.

Through the APTw images in the sagittal, transverse and coronal directions, target pathology can be revealed from different directions, improving the accuracy of clinical diagnosis.

Furthermore, the CEST pre-saturation sequence in the CEST-MRI sequence proposed in an embodiment of the present disclosure has a very high duty ratio. For instance, the CEST pre-saturation sequence shown in FIG. 3 has a duty ratio of 91%, the high duty ratio helping to attain the maximum attainable CEST contrast when scanning hardware is restricted.

Furthermore, the CEST-MRI sequence proposed in an embodiment of the present disclosure enables full-brain 2.79 mm isotropic CEST imaging to be realized in 5 minutes with no obvious susceptibility artifacts. This characteristic meets the condition for CEST imaging to be used for conventional clinical applications.

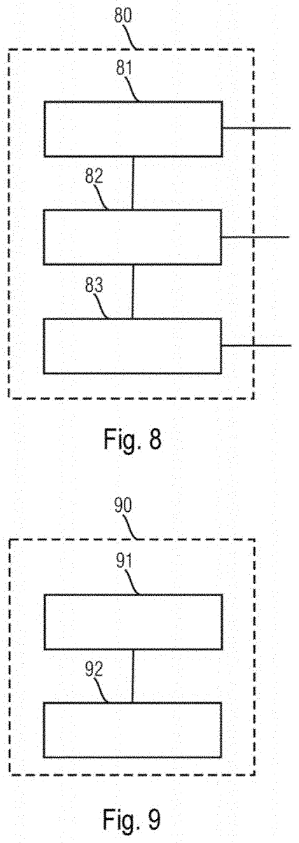

FIG. 8 is a CEST-MRI sequence generating apparatus provided in accordance with one or more embodiments of the present disclosure. In particular, FIG. 8 is a structural schematic diagram of a CEST-MRI sequence generating apparatus 80 provided in an embodiment of the present disclosure. The apparatus 80 may be located on, integrated as part of, and/or in communication with an MRI device. The apparatus 80 may include, for example, a pre-saturation pulse generating and transmitting module/circuitry 81, a fat-suppression pulse generating and transmitting module/circuitry 82, and an excitation and refocusing pulse generating and transmitting module/circuitry 83. The pre-saturation pulse generating and transmitting module/circuitry 81, fat-suppression pulse generating and transmitting module/circuitry 82, and excitation and refocusing pulse generating and transmitting module/circuitry 83 may be implemented as any suitable number and type of hardware processors, software, or combinations of these, in various embodiments.

In an embodiment, the pre-saturation pulse generating and transmitting module/circuitry 81 generates a pre-saturation pulse and transmits the pre-saturation pulse when a CEST-MRI scanning process starts. The fat-suppression pulse generating and transmitting module/circuitry 82 generates a fat-suppression pulse and transmits the fat-suppression pulse when the pre-saturation pulse generating and transmitting module/circuitry 81 has transmitted the pre-saturation pulse. The excitation and refocusing pulse generating and transmitting module/circuitry 83 generates an excitation pulse and transmits the excitation pulse when the fat-suppression pulse generating and transmitting module/circuitry 82 has transmitted the fat-suppression pulse, and generates multiple non-slice-selective refocusing square-wave pulses and transmits the multiple non-slice-selective refocusing square-wave pulses when transmission of the excitation pulse has ended.

In an embodiment, the pre-saturation pulse generated and transmitted by the pre-saturation pulse generating and transmitting module/circuitry 81 may be a non-slice-selective pulse, and the fat-suppression pulse generated and transmitted by the fat-suppression pulse generating and transmitting module/circuitry 82 may be a non-slice-selective pulse.

In an embodiment, the excitation pulse generated by the excitation and refocusing pulse generating and transmitting module/circuitry 83 may be a square-wave pulse or a non-square-wave pulse, and the refocusing square-wave pulses generated by the excitation and refocusing pulse generating and transmitting module/circuitry 83 may satisfy one or more of the following conditions: 50≤number of refocusing square-wave pulses≤250, 0.8 ms≤width of refocusing square-wave pulses≤1.5 ms, 2 ms≤interval between refocusing square-wave pulses≤5 ms.

Moreover, embodiments include each of the refocusing square-wave pulses generated by the excitation and refocusing pulse generating and transmitting module/circuitry 83 having the same flip angle. Alternatively, embodiments include, for T1 and T2 values of imaged tissue and a k-space signal intensity distribution curve to be realized, the Bloch equations being used to calculate (e.g. via one or more components of the apparatus 80 and/or the apparatus 90) the flip angles of each of the refocusing square-wave pulses.

In embodiments, the excitation and refocusing pulse generating and transmitting module/circuitry 83 may be configured to generate a SPACE sequence and transmitting the same.

FIG. 9 is a CEST-MRI sequence generating apparatus provided in accordance with one or more embodiments of the present disclosure. In particular, FIG. 9 shows a structural schematic diagram of a CEST-MRI sequence generating apparatus 90 provided in an embodiment of the present disclosure. The apparatus 90 may located on, integrated as part of, and/or in communication with an MRI device. The apparatus 90 may include, for example one or more processors 91 and a memory 92. In an embodiment, an application program executable by the one or more processors 91 may be stored in the memory 92 (e.g. a non-transitory computer-readable medium), for causing the one or more processors 91 to perform one or more steps of the CEST-MRI sequence generating method as described herein (e.g. steps 101-104 as discussed above with reference to FIG. 1 and/or steps 201-203 as discussed above with reference to FIG. 2).

The CEST-MRI sequence generating apparatus 80 and/or the CEST-MRI sequence generating apparatus 90 may include additional components not shown in the Figures for purposes of brevity. For instance, the CEST-MRI sequence generating apparatus 80 and/or the CEST-MRI sequence generating apparatus 90 may include one or more processors (in addition to or included as part of the components shown in FIGS. 8 and 9) that may generate, obtain, and/or cause a CEST image to be displayed (via a display that is not shown in the Figures) based upon the transmitted CEST pre-saturation pulse, the fat-suppression pulse, the excitation pulse, and/or the multiple non-slice-selective refocusing square-wave pulses (e.g. the images shown and described herein with respect to FIGS. 4-7).

Embodiments of the present disclosure also provide a readable storage medium (e.g. a non-transitory computer-readable medium), having instructions (e.g. a computer program) stored thereon. These instructions, when executed by one or more processors, may cause the one or more processors or device associated therewith to realize one or more steps of the CEST-MRI sequence generating method as described herein (e.g. steps 101-104 as discussed above with reference to FIG. 1 and/or steps 201-203 as discussed above with reference to FIG. 2).

Thus, embodiments include machine-readable instruction(s) being stored on the computer-readable storage medium. The machine-readable instruction, when executed by one or more processors, may thus cause the one or more processors to perform any one of the methods described above. Furthermore, embodiments include a system or apparatus being equipped with a readable storage medium; software program code realizing a function of any one of the embodiments above may be stored on the readable storage medium, and a computer or processor of the system or apparatus may be caused to read and execute a machine-readable instruction stored in the readable storage medium.

In such a scenario, program code read from the readable storage medium may itself realize a function of any one of the embodiments above, hence machine-readable code and the readable storage medium storing the machine-readable code form part of the present disclosure.

Examples of readable storage media include floppy disks, hard disks, magneto-optical disks, optical disks (such as CD-ROM, CD-R, CD-RW, DVD-ROM, DVD-RAM, DVD-RW, DVD+RW), magnetic tapes, non-volatile memory cards and ROM. Optionally, program code may be downloaded (e.g. from a server computer or a cloud) via a suitable communication network.

Those skilled in the art should understand that various changes in form and amendments may be made to the embodiments disclosed above without deviating from the substance of the disclosure. Thus, the scope of protection of the present disclosure shall be defined by the attached claims and elsewhere throughout the disclosure as described herein.

It must be explained that not all of the steps and module/circuitry in the flows and system structure diagrams above are necessary; certain steps or module/circuitry may be omitted according to actual requirements. Moreover, the apparatuses described herein (e.g., apparatuses 80 and/or 90) may include additional fewer, or alternative components. Furthermore, the various module/circuitry components as discussed herein are separated for ease of explanation, although embodiments include the functionality, hardware, and/or software associated with these modules/circuitry being combined or separated in accordance with a particular application, the availability of hardware components, etc. The apparatus structures described in the embodiments above may be physical structures, and may also be logical structures, i.e. some module/circuitry might be realized by the same physical entity, or some module/circuitry might be realized by multiple physical entities, or realized jointly by certain components in multiple independent devices. Also, the order in which steps are executed is not fixed, but may be adjusted as required

The present disclosure has been displayed and explained in detail above by means of the accompanying drawings and preferred embodiments, but the present disclosure is not limited to these disclosed embodiments. Based on the embodiments described above, those skilled in the art will know that further embodiments of the present disclosure, also falling within the scope of protection of the present disclosure, could be obtained by combining code checking means in different embodiments above.

What is claimed is:

1. A method for generating a Chemical Exchange Saturation Transfer-Magnetic Resonance Imaging (CEST-MRI) sequence for obtaining a CEST image of a scanned region, the method comprising:
transmitting, via an MRI device, a CEST pre-saturation pulse;
after the transmission of the CEST pre-saturation pulse, transmitting, via the MRI device, a fat-suppression pulse;
after the transmission of the fat-suppression pulse, transmitting, via the MRI device, an excitation pulse;
after the transmission of the excitation pulse, transmitting, via the MRI device, multiple non-slice-selective refocusing square-wave pulses; and
obtaining, via the MRI device, a CEST image based upon the transmitted CEST pre-saturation pulse, the fat-suppression pulse, the excitation pulse, and the multiple non-slice-selective refocusing square-wave pulses.

2. The method as claimed in claim 1, wherein the CEST pre-saturation pulse and the fat-suppression pulse are both non-slice-selective pulses.

3. The method as claimed in claim 1, wherein the excitation pulse is a square-wave pulse.

4. The method as claimed in claim 1, wherein the excitation pulse is a non square-wave pulse.

5. The method as claimed in claim 1, wherein the refocusing square-wave pulses satisfy one or more of the following conditions:
50≤a number of refocusing square-wave pulses≤250;
0.8 ms≤a width of each of the refocusing square-wave pulses≤1.5 ms; and
2 ms≤an interval between adjacent refocusing square-wave pulses≤5 ms.

6. The method as claimed in claim 1, wherein each of the refocusing square-wave pulses have the same flip angle.

7. The method as claimed in claim 1, further comprising:
calculating, using T1 and T2 values of imaged tissue and a k-space signal intensity distribution curve to be realized, flip angles of each of the refocusing square-wave pulses using the Bloch equations.

8. The method as claimed in claim 1, wherein transmitting the excitation pulse and transmitting the multiple non-slice-selective refocusing square-wave pulses comprises:
transmitting a Sampling Perfection with Application-optimized Contrasts by using different flip angle Evolutions (SPACE) sequence.

9. An apparatus associated with a magnetic resonance imaging (MRI) device, the apparatus being configured to generate a Chemical Exchange Saturation Transfer-Magnetic Resonance Imaging (CEST-MRI) sequence, the apparatus comprising:
a pre-saturation pulse generating and transmitting circuitry configured to transmit a CEST pre-saturation pulse when a CEST-MRI scanning process is started;
a fat-suppression pulse generating and transmitting circuitry configured to transmit a fat-suppression pulse after the transmission of the pre-saturation pulse;
an excitation and refocusing pulse generating and transmitting circuitry configured to transmit an excitation pulse after the transmission of the fat-suppression pulse, and to transmit multiple non-slice-selective refocusing square-wave pulses after the transmission of the excitation pulse; and
one or more processors configured to obtain a CEST image based upon the transmitted CEST pre-saturation pulse, the fat-suppression pulse, the excitation pulse, and the multiple non-slice-selective refocusing square-wave pulses.

10. The apparatus as claimed in claim 9, wherein the pre-saturation pulse generating and transmitting circuitry is configured to transmit each of the CEST pre-saturation pulse and the fat-suppression pulse as a respective non-slice-selective pulse.

11. The apparatus as claimed in claim 9, wherein the excitation and refocusing pulse generating and transmitting circuitry is configured to transmit the excitation pulse as a square-wave pulse.

12. The apparatus as claimed in claim 9, wherein the excitation and refocusing pulse generating and transmitting circuitry is configured to transmit the excitation pulse as a non square-wave pulse.

13. The apparatus as claimed in claim 9, wherein the excitation and refocusing pulse generating and transmitting circuitry is configured to transmit the refocusing square-wave pulses to satisfy one or more of the following conditions:
50≤a number of refocusing square-wave pulses≤250;
0.8 ms≤a width of each of the refocusing square-wave pulses≤1.5 ms; and
2 ms≤an interval between refocusing square-wave pulses≤5 ms.

14. The apparatus as claimed in claim 9, wherein the excitation and refocusing pulse generating and transmitting circuitry is configured to transmit each of the refocusing square-wave pulses having the same flip angle.

15. The apparatus as claimed in claim 9, wherein the excitation and refocusing pulse generating and transmitting circuitry is configured to calculate, using T1 and T2 values of imaged tissue and a k-space signal intensity distribution curve to be realized, flip angles of each of the refocusing square-wave pulses using the Bloch equations.

16. The apparatus as claimed in claim 9, wherein the excitation and refocusing pulse generating and transmitting circuitry is configured to transmit the excitation pulse and the multiple non-slice-selective refocusing square-wave pulses by generating a SPACE (Sampling Perfection with Application-optimized Contrasts by using different flip angle Evolutions) sequence and transmitting the SPACE sequence.

17. A non-transitory computer readable storage medium having instructions stored thereon that, when executed by one or more processors associated with a Magnetic Resonance Imaging (MRI) device, cause the MRI device to generate a Chemical Exchange Saturation Transfer-Magnetic Resonance Imaging (CEST-MRI) sequence and to obtain a CEST image of an MRI-scanned region by:
transmitting a CEST pre-saturation pulse;
after the transmission of the CEST pre-saturation pulse, transmitting a fat-suppression pulse;
after the transmission of the fat-suppression pulse, transmitting an excitation pulse;
after the transmission of the excitation pulse, transmitting multiple non-slice-selective refocusing square-wave pulses; and
obtaining, a CEST image based upon the transmitted CEST pre-saturation pulse, the fat-suppression pulse, the excitation pulse, and the multiple non-slice-selective refocusing square-wave pulses.
